(19) United States
(12) Patent Application Publication
(10) Pub. No.: US 2016/0027989 A1
(43) Pub. Date: Jan. 28, 2016

(54) ROBUST PIEZOELECTRIC FLUID MOVING DEVICES AND METHODS

(71) Applicant: Mide Technology Corporation, Medford, MA (US)

(72) Inventors: Christopher Ludlow, Melrose, MA (US); Jeffrey Richard Court, Stow, MA (US); Cody John O'Sullivan, Somerville, MA (US); Stephen William Hanly, Charlestown, MA (US); Brian Thomas Durant, Medford, MA (US)

(21) Appl. No.: 14/339,597

(22) Filed: Jul. 24, 2014

(51) Int. Cl. H01L 41/053; H01L 41/04; H01L 41/23; H01L 41/09

(52) U.S. Cl. CPC H01L 41/053; H01L 41/0973; H01L 41/042; H01L 41/23

(57) ABSTRACT

A method of making a piezoelectric fluid moving device, (e.g., a fan or synthetic jet actuator) includes forming at least a first electrode on a base substrate and disposing a spacer frame about the first electrode. A piezoelectric substrate is placed within the frame and over the first electrode. A cover substrate is located on the spacer frame. The cover substrate and spacer frame are laminated to each other and to the base substrate encapsulating the piezoelectric substrate between the cover substrate and the base substrate for a long life device.

### FIELD OF THE INVENTION

The subject invention relates to piezoelectric fans, synthetic jets, and similar devices which move a fluid such as air.

### BACKGROUND OF THE INVENTION

Fans are used to cool electronic devices and systems. Motor driven rotary fans have several drawbacks as noted in U.S. Pat. No. 5,861,703 incorporated herein by this reference. One potential solution is to use a piezoelectric fan. See the '703 patent and also U.S. published Patent No. 2007/0090726 incorporated herein by this reference.

But, current piezoelectric fans may suffer from problems such as a lack of durability, high manufacturing costs, and the like. In some applications, a fan is needed which can survive many years of service. Some prior piezoelectric fans are subject to contamination by dust, humidity, and other contaminants that could cause the fan to fail.

Synthetic jet devices are also used for both cooling and flow applications. Electromagnetic based synthetic jet devices have drawbacks. Piezoelectric synthetic jet devices offer a low profile, low power solution for synthetic jet cooling and flow applications. See U.S. Pat. Nos. 8,418,934; 2008/0137289; and 7,633,753 incorporated herein by this reference.

But, piezoelectric synthetic jet devices may also suffer from problems such as a lack of durability, high manufacturing costs, and the like. In some applications, a synthetic jet device is required that can survive many years of service. Some synthetic jet devices are subject to contamination by dust, humidity, corrosive agents, water, and other contaminants that could cause the synthetic jet device to fail.

### SUMMARY OF THE INVENTION

The invention, in one aspect, results in new piezoelectric devices (e.g., fans and jet actuators) which have a long life, which are not subject to contamination, and which are durable. A new manufacturing method, in one example, results in a long life, durable piezoelectric device with a hermetically sealed piezoelectric substrate and its associated electrodes.

Featured is a method of making a piezoelectric fluid moving device. One method comprises forming at least a first electrode on a base substrate, disposing a spacer frame about the first electrode, and placing a piezoelectric substrate within the frame and over the first electrode. A cover substrate is placed on the spacer frame and the cover substrate and spacer frame are laminated to each other and to the base substrate encapsulating the piezoelectric substrate between the cover substrate and the base substrate. One benefit is a long life device. In one example, the base substrate is an elongate fan blade. In another example, the base substrate forms a synthetic jet actuator.

The method may further include forming an electrode on the inside of the cover substrate contacting the piezoelectric substrate. This method may further include forming a first electrode lead on the base substrate, forming a partial second electrode lead on the base substrate, and forming a partial second electrode lead on the inside of the cover substrate contacting the partial second electrode lead on the base substrate after lamination.

One method includes forming an electrode on an opposite side of the base substrate and including a spacer frame, a piezoelectric substrate, and a cover substrate laminated on the opposite side of the base substrate.

In some examples, the base substrate includes first and second electrodes. The piezoelectric substrate includes a top electrode extending around an edge of the piezoelectric substrate to the bottom of the piezoelectric substrate contacting the base substrate first electrode. The piezoelectric substrate includes a bottom electrode contacting the base substrate second electrode.

The base substrate may be an FR-4 laminate, the cover substrate may be an FR-4 laminate, and the spacer frame may be made of a thermoplastic polymer or FR-4.

Laminating may include using an epoxy preferably with a high glass transition temperature. Laminating may include heating and using pressure.

In one version, the device is used at a working temperature and the method includes configuring the device to have a natural frequency at said working temperature. One method may include driving the device at a fixed frequency at or proximate a designed natural frequency. In another design, the natural frequency of the device at a given temperature is periodically determined and the device is driven at said frequency. One method further includes adding one or more sensors to the base substrate. One method further includes adding drive circuitry to the base substrate.

Also featured is a piezoelectric fluid moving device comprising a base substrate including at least a first electrode on one surface thereof, a spacer frame about the first electrode, and a piezoelectric substrate within the spacer frame over the first electrode. A cover substrate on the spacer frame is laminated to the base substrate encapsulating the piezoelectric substrate between the base substrate and the cover substrate. In one example, the base substrate is an elongate fan blade. In another example, the base substrate forms a synthetic jet actuator.

The device may further include an electrode on the inside of the cover substrate contacting the piezoelectric substrate.

The base substrate may include a first electrode lead and a partial second electrode lead. The cover substrate includes a partial second electrode lead contacting the partial second electrode lead on the base substrate. One device may further include an electrode on an opposite side of the base substrate, and a spacer frame, a piezoelectric substrate, and a cover substrate laminated to the opposite side of the base substrate.

In one version, the device base substrate includes first and second electrodes and the piezoelectric substrate includes a top electrode extending around an edge of the piezoelectric substrate to the bottom of the piezoelectric substrate contacting the base substrate first electrode. The piezoelectric substrate includes a bottom electrode contacting the base substrate second electrode.

The device may be configured to have a natural frequency at or proximate a working temperature of the device. A fixed frequency drive circuit on the base substrate may drive the device at a frequency at or proximate the natural frequency.

The device may further include one or more sensors and device drive circuitry on the base substrate. In one example, the device may be integrated into a printed circuit board. In one example, a drive circuit is configured to operate the device based on the temperature output by a temperature sensor.

The subject invention, however, in other embodiments, need not achieve all these objectives and the claims hereof should not be limited to structures or methods capable of achieving these objectives.

BRIEF DESCRIPTION OF THE SEVERAL VIEWS OF THE DRAWINGS

Other objects, features, and advantages will occur to those skilled in the art from the following description of a preferred embodiment and the accompanying drawings, in which:

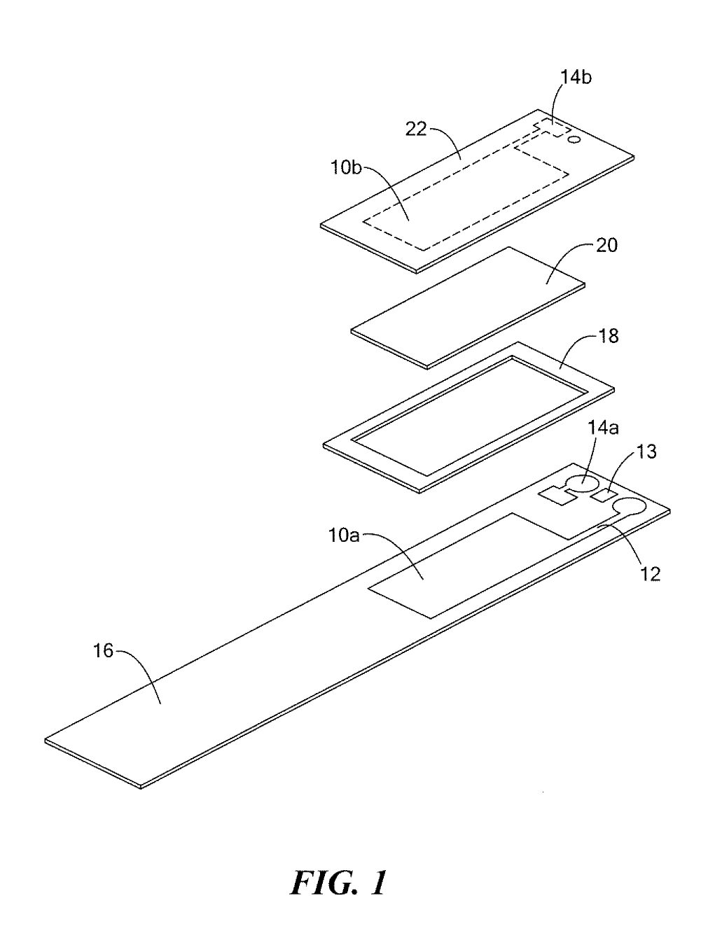

FIG. 1 is a schematic exploded view showing an example of the assembly of a piezoelectric fan in accordance with the invention; and

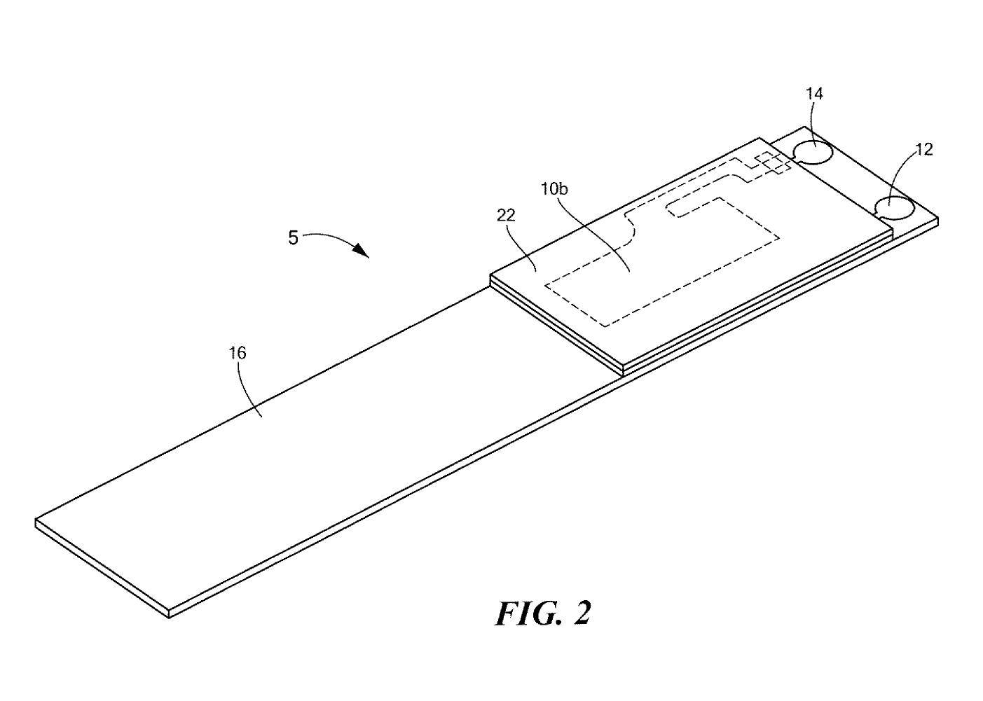

FIG. 2 is a schematic view of a fully assembled piezoelectric fan in accordance with an example of the invention.

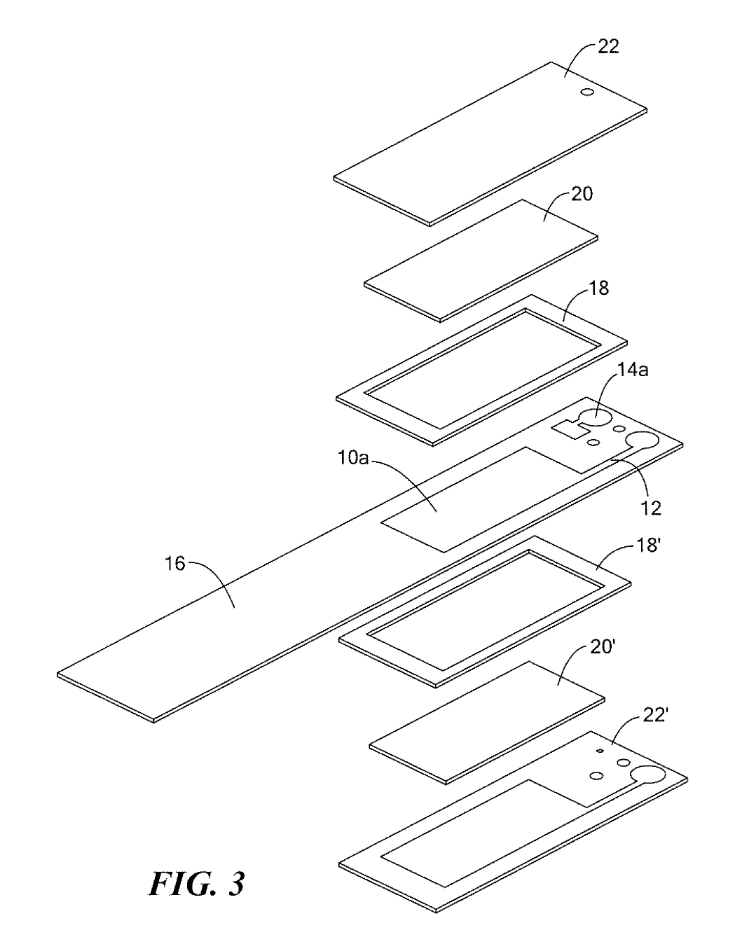

FIG. 3 is an exploded view showing an example of the assembly of a piezoelectric fan with top and bottom piezoelectric substrates;

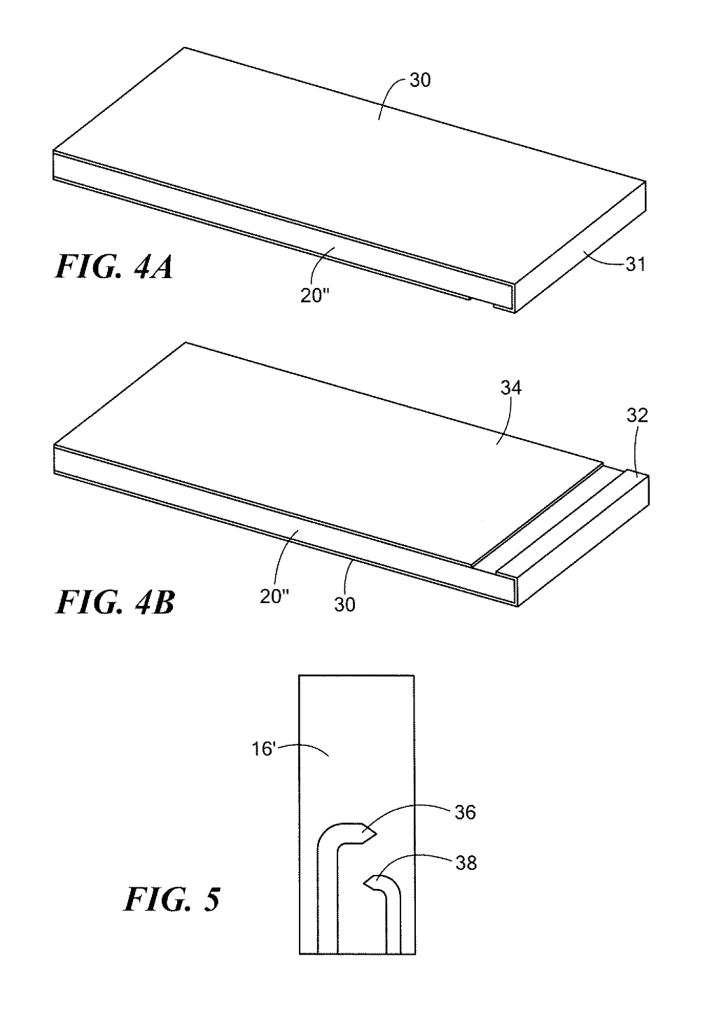

FIG. 4A is a view of the top of a piezoelectric substrate with a top electrode wrapping around an edge of the piezoelectric substrate to the bottom of the piezoelectric substrate;

FIG. 4B is a bottom view of the piezoelectric substructure of FIG. 4A;

FIG. 5 is a schematic view of the fan electrodes for the piezoelectric substrate of FIG. 4;

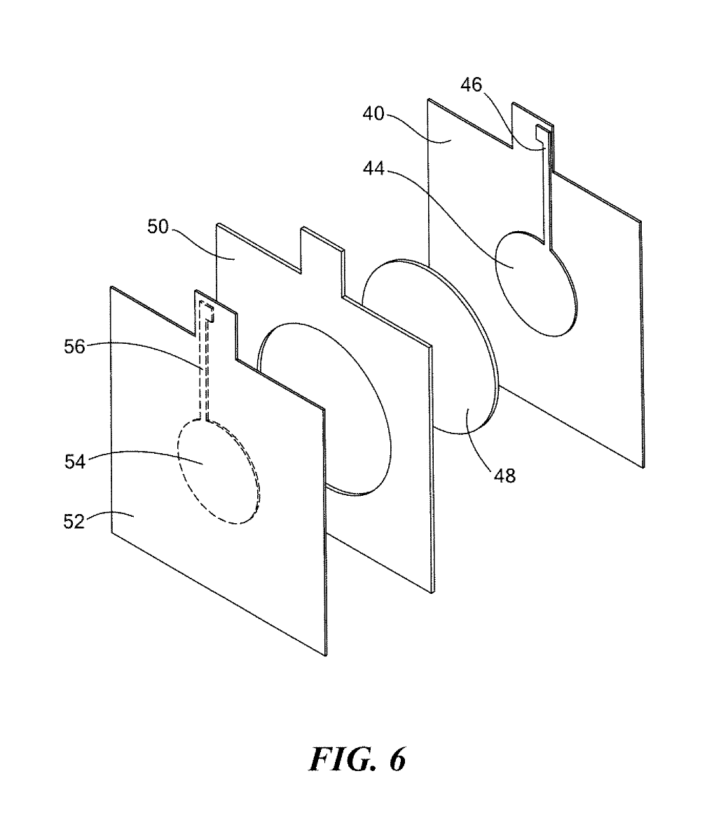

FIG. 6 is a schematic view showing an example of the assembly of a piezoelectric synthetic jet device actuator in accordance with examples of the invention;

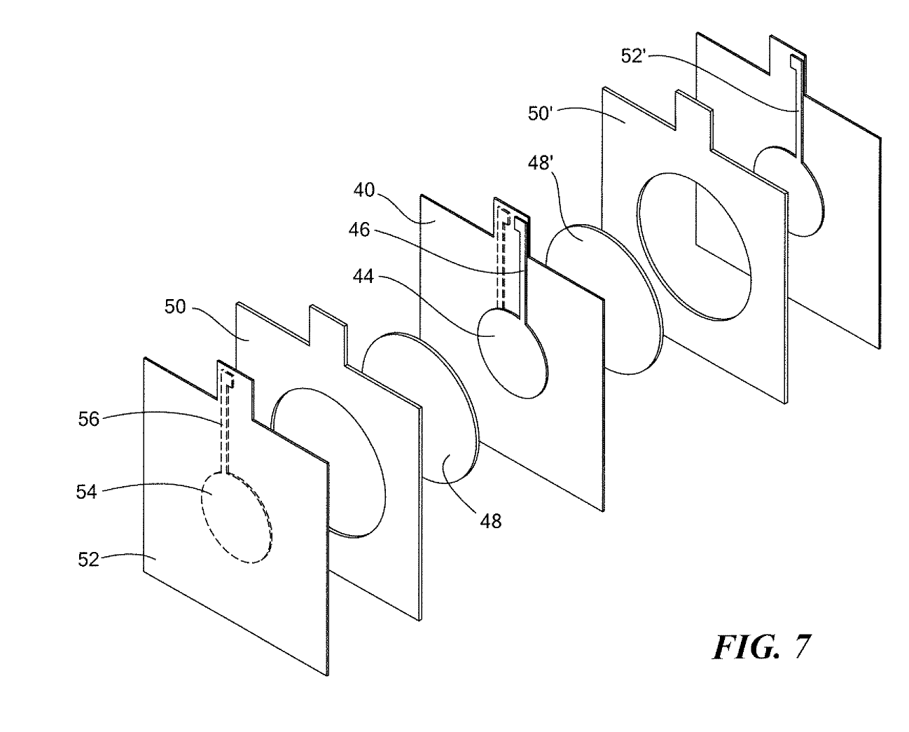

FIG. 7 is a schematic exploded view showing an example of the assembly of another piezoelectric synthetic jet device actuator with top and bottom with piezoelectric substrates;

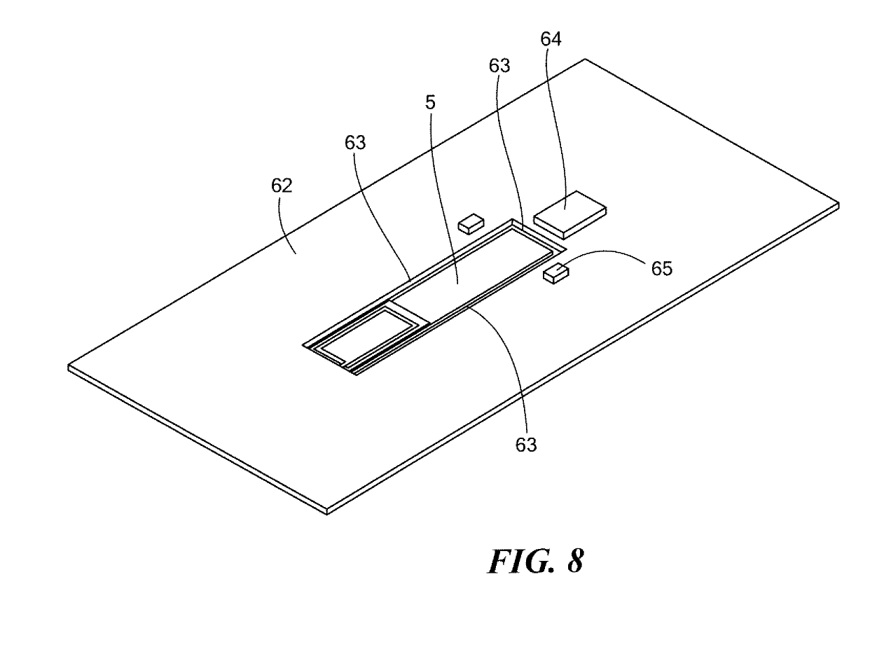

FIG. 8 is a schematic view showing a piezoelectric fan blade integrated into a printed circuit board (PCB) assembly;

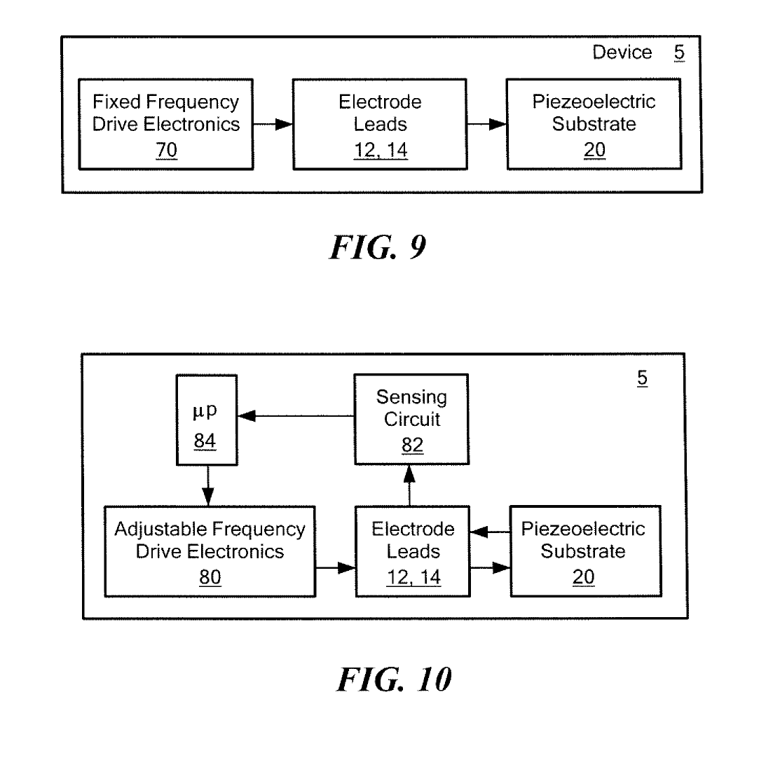

FIG. 9 is a block diagram showing the primary subsystems associated with a piezoelectric fluid moving device with fixed frequency drive electronics preferably incorporated into the materials of the piezoelectric fluid moving device; and

FIG. 10 is a block diagram showing the primary components associated with a piezoelectric fluid moving device with adjustable frequency drive electronics.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

In one version, a first electrode 10a, lead 12, and a portion 14a of another lead are formed on the top of a base substrate such as one end of fan blade 16. The electrodes and/or leads can be deposited or etched. Fan blade 16 may be made of the materials typically used to manufacture printed circuit boards, for example, FR-4 PCG laminate material clad with the metallic (e.g., copper) top coating etched to form electrode 10a, lead 12, and partial lead 14a. The blade 16 may be 0.010″ thick, 0.025-0.075″ wide, and 3.0-4.5″ long.

Spacer frame 18 (made of, for example, a thermoplastic polymer such as polysulfone or FR-4) is disposed onto the top of blade 16 about (around and/or partially on) electrode 10a. Piezoelectric material substrate 20 is placed in frame 18 over first electrode 10a. Piezoelectric substrate material 20 may be lead zirconate titanate (PZT-5A). A second electrode 10b may be formed by etching the bottom of metallic (e.g., copper) clad cover substrate 22. The etching process may also form partial lead 14b which will contact partial lead 14a formed on blade 16. Cover substrate 22 may also be made of FR-4 material. In FIG. 1, the second electrode 10b is on the bottom of cover substrate 22 but is visible through the substrate. Cover substrate 22 is placed on frame 18 so electrode 10b is on top of the corresponding electrode of piezoelectric material substrate 20.

All these layers are laminated together. See U.S. Pat. Nos. 5,656,882; 5,687,462; 6,069,443; 6,198,206; 6,359,371; 6,376,867; and 6,420,819 incorporated herein by this reference. A high glass transition temperature epoxy such as Hexcel Redux 312 is preferably used between and about the periphery of the individual layers along with heat and pressure (e.g., two tons of pressure using an industrial press) during the laminating process. The epoxy glass transition temperature is preferably higher than the operating temperature of the device. In one example, the epoxy is disposed between frame 18 and blade 16, between piezoelectric material 20 and electrode 10a, between electrode 10b and piezoelectric material 20, and between substrate 22 and frame 18 to fully encapsulate piezoelectric material 20 and electrodes 10a and 10b on blade 16. During the lamination process, partial conductive lead 10b makes contact with partial conductive lead 14a. Lead 10a contacts one surface electrode of piezoelectric substrate 20 and lead 10b contact the opposite surface electrode of the piezoelectric substrate 20. FIG. 2 shows a completed fan 5. Drive electronics contact leads 12 and 14 and may be incorporated on substrate 16 and protected by cover 22.

Using this method, a long life, durable piezoelectric fan is manufactured with a hermetically sealed piezoelectric material device and its associated electrodes. The piezoelectric material is not subject to contamination and is more robust than prior fans. Such a fan may survive 15 or more years in the field. Fully encapsulating the piezoelectric material and electrical connections from dust, humidity, contaminants, and the like results in a piezoelectric fan which is not as subject to failure like known fans in the prior art. The use of materials which do not absorb water such as FR-4 also increases the life of the fan. The use of electrodes which are located as far from each other as possible limits the potential for short circuiting. The use of etched circuits allows for any number of different form factors to be designed and manufactured or any number of electrode terminations to be integrated into the design.

Another potential benefit of using copper etched surfaces is that many of the electronics to drive the piezo could be integrated into the design. These electronics could also be protected the same as the piezoelectric element. FIG. 1 shows, for example of a piezeo fan driver chip 13, (e.g., TI part no. DRV8662).

A plurality of such piezoelectric fans can be manufactured in a single run by using sheets or rolls of the various layers each with a number of fan blade components and then routing or striping the individual fan blades from the consolidated layup. In one example, a sheet of FR-4 had 39 fan blade structures 16 as shown in FIG. 1, for example, and electrodes 10a and leads 12 and 14. Another sheet had the spacer frames, and the like.

These fans can be used to blow air over electronic components and/or through or over a heat sink used to cool an electronic component or system by attaching a driver circuit to leads 14 and 12.

In FIG. 3, another frame 18′, piezoelectric substrate 20′, and cover substrate 22′ are laminated to the bottom of base substrate 16. Base substrate 16 will include an underside electrode and leads like shown for the top of substrate 16.

FIG. 4 shows an embodiment with piezoelectric substrate 20′ with a top electrode 30 extending around the edge 31 of the piezoelectric substrate to the bottom of the piezoelectric substrate 20″ as shown at 32, e.g., a wraparound electrode design. Piezoelectric substrate 20″ also includes a second spaced electrode 34 on the bottom thereof. Now, base substrate 16′, FIG. 5 includes first and second spaced electrodes 36 and 38. In this embodiment, the cover substrate need not include an inner side electrode and/or leads. After lamination with a spacer frame and cover substrate, the piezoelectric substrate electrode at 32 contacts the base substrate electrode 38 and the piezoelectric substrate electrode 34 contacts base substrate electrode 36. Again, the piezoelectric substrate is fully protected and encapsulated between the cover substrate and the base substrate.

In another embodiment, the piezoelectric fluid moving device is constructed as a piezoelectric actuator of the diaphragm portion of a synthetic jet device. See U.S. Pat. No. 8,418,943 incorporated herein by this reference.

In FIG. 6, the base substrate is 40 and includes electrode 44 and lead 46 thereon. Base substrate 40 may be FR-4. Piezoelectric substrate 48 is within frame 50 and cover substrate 52 with electrode 54 and lead 56 is laminated to base substrate 40 encapsulating and hermetically sealing piezoelectric substrate 48 and the associated electrodes and leads thereof.

In FIG. 7, a cover substrate 52′, spacer frame 50′ and piezoelectric substrate 48′ are added to the backside of the base substrate 40 which will now include a backside electrode and lead or leads (not shown) contacting piezoelectric substrate 48′ after lamination.

These devices can be used to move fluid over electronic components and/or through or over a heat sink used to cool an electronic component or system by attaching a driver signal to leads 14 and 12 or by providing power to leads 14 and 12 if a driver circuit is integrated directly into the device. These devices can also be used to direct fluid (e.g., air) directly at components or systems or into open space. These devices could also be used to shape flow over flow control surfaces such as airplane rudders, fuselages, ailerons, automotive panels, wind turbine blades, and the like.

These devices, being made of FR-4, the same materials that PCBs are constructed of, can also be integrated directly into a PCB assembly to cool electronic components or systems. FIG. 8 shows PCB 62 and piezoelectric fan blade 5 routed on three sides from the PCB as shown at 63. Fan blade 5 cools electronic components such as shown at 64. Thus, the device (here a fan blade) is integrated into the printed circuit board.

If a thermocouple or other temperature reporting device as shown at 65 is included, the driving circuitry for fan 5 (which may be on the fan blade or on PCB 62) can be configured to drive the fan when a prescribed temperature is reported by the thermocouple and to turn the fan blade off when the temperature reported by the thermocouple falls below the prescribed temperature. This feature helps ensure a long life for the fan blade since it is only operated when needed.

In some situations, cooling is only needed when the system reaches a critical temperature, say 80 degrees C. A typical device's natural frequency may change by ˜10% over the useable temperature range of −40 C. to 125 C. To improve lifetime/durability, it would be preferred not to drive the fan “hard” (e.g., at resonance) when it is not needed, below 60 C., for example. In embodiments where the drive electronics 70, FIG. 9 are fixed frequency, which is advantageous in a less expensive and more robust device, the fan can be designed such that it reaches optimal performance (where the fixed drive frequency equals the natural frequency of the device) at that desired temperature. So, if for a majority of the device's life the system was “cool,” the device would not be overtaxed. However, when the system requires cooling, the device would automatically increase its fluid flow as a direct result of the rise in temperature. By varying the geometry (thickness, width, length) and/or the stiffness of the materials used, the device can be configured to have a specific natural frequency.

In other embodiments, it may be desired to control the natural frequency of the device to always provide optimal fluid flow regardless of the ambient temperature. A drive circuit 80, FIG. 10 would have the ability to adjust the output frequency (and amplitude for more control) of the signal going to the device. One challenge is knowing what the natural frequency of your device is at any given moment or temperature.

One solution is to use the inverse piezoelectric property of sensing a signal from the piezoelectric element 20. It would be possible to have a circuit 82 that briefly and momentarily turns off power to the piezoelectric substrate 20 and then senses the output of the piezoelectric element as the structure rings out. The decaying output signal will have a frequency component that is equal to the natural frequency of the structure at the correct temperature. A peak find routine on microprocessor 84 determines the new natural frequency, adjusts the drive signal 80 to match that frequency, and then re-powers the device at this new drive frequency. This could all be done in a few milli-seconds.

This approach can also be used for health monitoring of the device. For example, if circuit 82 includes additional capability such as thermal sensors and the ability to communicate back to a central system, the output signal from the piezoelectric substrate 20 (both the frequency as per before and the amplitude) can be measured to determine if there has been any changes since the last time or times it was measured. A change, specifically a reduction in frequency for a given temperature, may indicate that the device is beginning to fail or was damaged.

Another option for changing the drive frequency would be to use an embedded thermal sensor in circuit 82 and then include a lookup table where processor 84 correlates the drive frequency to the temperature. This could also be used to “turn on” the fan when a certain temperature threshold is reached. A zero power thermal sensor could be used to perform this turn on function as well. Benefits include lower overall power consumption and improved lifetime as the fan undergoes less cycles.

Embedding any drive circuitry (see U.S. Pat. No. 4,595,338 incorporated herein by this reference) with the inventive packaging process is also beneficial. The packaging materials are usually copper etched FR4 which is the exact material printed circuit boards are constructed of. In this instance, a power line, e.g., 3.3V or 5V DC (something standard for most electronics boards) is provided to leads 12, 14 and the entire voltage step up, frequency control, and other electronics are embedded into the device 5 (e.g., a fan or jet device).

In another embodiment, a fan can be built directly into a PCB assembly. Again, since the fan includes the same materials as PCB, a device can be integrated into the PCB construction at strategic locations to cool various systems/components. See FIG. 8.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

1. A method of making a piezoelectric fluid moving device, the method comprising:
forming at least a first electrode on a base substrate;
disposing a spacer frame about the first electrode;
placing a piezoelectric substrate within the frame and over the first electrode;
placing a cover substrate on the spacer frame; and
laminating the cover substrate and spacer frame to each other and to the base substrate encapsulating the piezoelectric substrate between the cover substrate and the base substrate.

2. The method of claim 1 in which the base substrate is an elongate fan blade.

3. The method of claim 1 in which the base substrate forms a synthetic jet actuator.

4. The method of claim 1 further including forming an electrode on the inside of the cover substrate contacting the piezoelectric substrate.

5. The method of claim 4 further including forming a first electrode lead on the base substrate, forming a partial second electrode lead on the base substrate, and forming a partial second electrode lead on the inside of the cover substrate contacting the partial second electrode lead on the base substrate after lamination.

6. The method of claim 1 further including forming an electrode on an opposite side of the base substrate and including a spacer frame, a piezoelectric substrate, and a cover substrate laminated on the opposite side of the base substrate.

7. The method of claim 1 in which the base substrate includes first and second electrodes and the piezoelectric substrate includes a top electrode extending around an edge of the piezoelectric substrate to the bottom of the piezoelectric substrate contacting the base substrate first electrode and the piezoelectric substrate includes a bottom electrode contacting the base substrate second electrode.

8. The method of claim 1 in which the base substrate is an FR-4 laminate.

9. The method of claim 1 in which the cover substrate is an FR-4 laminate.

10. The method of claim 1 in which said spacer frame is made of a thermoplastic polymer or FR-4.

11. The method of claim 1 in which laminating includes using an epoxy.

12. The method of claim 7 in which said epoxy has a high glass transition temperature.

13. The method of claim 1 in which laminating includes heating.

14. The method of claim 10 in which laminating further includes using pressure.

15. The method of claim 1 in which the device is used at a working temperature and the method includes designing the device to have a natural frequency at said working temperature.

16. The method of claim 15 further including driving said device at a fixed frequency at or proximate said designed natural frequency.

17. The method of claim 1 further including periodically determining the natural frequency of the device at a given temperature and driving the device at said frequency.

18. The method of claim 1 further including adding one or more sensors to the base substrate.

19. The method of claim 1 further including adding drive circuitry to the base substrate.

20. A piezoelectric fluid moving device comprising:
a base substrate including at least a first electrode on one surface thereof;
a spacer frame about the first electrode;
a piezoelectric substrate within the spacer frame over the first electrode; and
a cover substrate on the spacer frame laminated to the base substrate encapsulating the piezoelectric substrate between the base substrate and the cover substrate.

21. The device of claim 20 in which the base substrate is an elongate fan blade.

22. The device of claim 20 in which the base substrate forms a synthetic jet actuator.

23. The device of claim 20 further including an electrode on the inside of the cover substrate contacting the piezoelectric substrate.

24. The device of claim 23 in which the base substrate includes a first electrode lead, the base substrate includes a partial second electrode lead, and the cover substrate includes a partial second electrode lead contacting the partial second electrode lead on the base substrate.

25. The device of claim 20 further including an electrode on an opposite side of the base substrate, and a spacer frame, a piezoelectric substrate, and a cover substrate laminated to the opposite side of the base substrate.

26. The device of claim 20 in which the base substrate includes first and second electrodes and the piezoelectric substrate includes a top electrode extending around an edge of the piezoelectric substrate to the bottom of the piezoelectric substrate contacting the base substrate first electrode and the piezoelectric substrate includes a bottom electrode contacting the base substrate second electrode.

27. The device of claim 20 in which the base substrate is an FR-4 laminate.

28. The device of claim 20 in which the cover substrate is an FR-4 laminate.

29. The device of claim 20 in which said spacer frame is made of a thermoplastic polymer or FR-4.

30. The device of claim 20 further including an epoxy laminating the cover substrate to the base substrate.

31. The device of claim 30 in which said epoxy has a high glass transition temperature.

32. The device of claim 20 in which the device is configured to have a natural frequency at or proximate a working temperature of the device.

33. The device of claim 32 further including a fixed frequency drive circuit on the base substrate driving said device at a frequency at or proximate the device natural frequency.

34. The device of claim 20 further including one or more sensors and device drive circuitry on the base substrate.

35. The device of claim 20 in which the device is integrated into a printed circuit board.

36. The device of claim 20 further including a temperature sensor and a drive circuit configured to operate the device based on the temperature output by the temperature sensor.
